(19) United States
(12) Patent Application Publication
(10) Pub. No.: US 2026/0247819 A1
(43) Pub. Date: Aug. 20, 2026

(54) DISPLAY PANEL AND DISPLAY DEVICE HAVING SAME

(71) Applicants: BEIJING BOE TECHNOLOGY DEVELOPMENT CO., LTD., Beijing (CN); BOE TECHNOLOGY GROUP CO., LTD., Beijing (CN)

(72) Inventors: Chunping LONG, Beijing (CN); Pan LI, Beijing (CN); Pan XU, Beijing (CN)

(21) Appl. No.: 19/471,140

(22) PCT Filed: Oct. 21, 2024
(86) PCT No.: PCT/CN2024/126202

§ 371 Date: Sep. 30, 2025

(30) Foreign Application Priority Data
Nov. 1, 2023 (CN) 202311443485.7

(51) Int. Cl. H10K 59/131; H10H 29/32; H10H 29/37; H10H 29/49; H10H 29/80; H10H 29/855; H10K 59/121; H10K 59/122; H10K 59/80

(52) U.S. Cl. CPC H10K 59/131; H10H 29/32; H10H 29/37; H10H 29/49; H10H 29/8321; H10H 29/8552; H10K 59/1213; H10K 59/1216; H10K 59/122; H10K 59/80515; H10K 59/8792

(57) ABSTRACT

Disclosed are a display panel and a display device having same. The display panel includes an array substrate including a base substrate, and thin film transistors, first signal lines extending in a first direction and spaced apart in a second direction, second signal lines extending in a second direction and spaced apart in the first direction, and metal blocks spaced apart in the first direction, which are arranged on the base substrate. The orthographic projections of the first signal lines on the base substrate intersect with the orthographic projections of the second signal lines on the base substrate; the orthographic projections of the metal blocks on the base substrate overlap the orthographic projections of the first signal lines on the base substrate; and the orthographic projections of the metal blocks on the base substrate do not overlap the orthographic projections of the second signal lines on the base substrate.

### CROSS-REFERENCE TO RELATED APPLICATIONS

This application claims priority to the Chinese patent application filed with China National Intellectual Property Administration Nov. 1, 2023, with application number 202311443485.7 and application name “Display panel and display device having same”, all contents of which are incorporated by reference in this application.

### TECHNICAL FIELD

The present disclosure relates to the field of display technology and in particular to a display panel and a display device thereof.

### BACKGROUND

At present, with the rapid development of science and technology, various display devices have gradually developed, such as liquid crystal display devices (LCD) and organic light-emitting diode display devices (OLED). Whether it is an LCD display device or an OLED display device, a flat layer is often formed during its production process. If the flatness of the flat layer is not enough, unevenness is likely to occur in the pixel, which will seriously affect the performance of the display device and the display effect of the display device.

### SUMMARY

Some embodiments of the present disclosure provide a display panel, including:
an array substrate including: a base substrate, a plurality of thin film transistors arranged on the base substrate, a plurality of first signal lines extending along a first direction and arranged at intervals along a second direction, a plurality of second signal lines extending along the second direction and arranged at intervals along the first direction, and a plurality of metal blocks arranged at intervals along the first direction;
an orthographic projection of the first signal lines on the base substrate intersects with an orthographic projection of the second signal lines on the substrate; an orthographic projection of the metal blocks on the base substrate overlaps with the orthographic projection of the first signal lines on the base substrate, and the orthographic projection of the metal blocks on the base substrate does not overlap with the orthographic projection of the second signal lines on the base substrate.

In some embodiments, the first signal lines and the second signal lines are arranged on different layers; and the metal blocks and the second signal lines are arranged on the same layer;
the first signal lines include: a plurality of first gate lines, a plurality of second gate lines, a plurality of first power supply voltage signal lines, a plurality of first reference voltage signal lines, a plurality of initialization voltage signal lines and a plurality of light emitting control signal lines;
the second signal lines include: a plurality of data lines, a plurality of second power supply voltage signal lines and a plurality of second reference voltage signal lines;
the first power supply voltage signal line is connected to the second power supply voltage signal line through a first through hole; an orthographic projection of the first through hole on the base substrate is located at an intersection of an orthographic projection of the first power supply voltage signal line on the base substrate and an orthographic projection of the second power supply voltage signal line on the base substrate;
the first reference voltage signal line is connected to the second reference voltage signal line through a second through hole; an orthographic projection of the second through hole on the base substrate is located at an intersection of an orthographic projection of the first reference voltage signal line on the base substrate and an orthographic projection of the second reference voltage signal line on the base substrate.

In some embodiments, the metal blocks include: a plurality of first electrode blocks,
an orthographic projection of the first electrode blocks on the base substrate overlaps with an orthographic projection of the first power supply voltage signal lines on the base substrate and an orthographic projection of the light emitting control signal lines on the base substrate; or, an orthographic projection of the first electrode blocks on the base substrate overlaps with an orthographic projection of the first power supply voltage signal lines on the base substrate, an orthographic projection of the light emitting control signal lines on the base substrate and an orthographic projection of the first gate lines on the base substrate; or, an orthographic projection of the first electrode blocks on the base substrate overlaps with an orthographic projection of the light emitting control signal lines on the base substrate and an orthographic projection of the first gate lines on the base substrate.

In some embodiments, the orthographic projection of the first electrode blocks on the base substrate and an orthographic projection of the second signal lines on the base substrate are spaced apart from each other.

In some embodiments, the first electrode block is connected to the second power supply voltage signal line to form a whole;
the orthographic projection of the first electrode blocks on the base substrate is spaced apart from an orthographic projection of the data lines on the base substrate and an orthographic projection of the second reference voltage signal lines on the base substrate.

In some embodiments, the first electrode block and the second reference voltage signal line are connected to form a whole;
the orthographic projection of the first electrode blocks on the base substrate is spaced apart from an orthographic projection of the data lines on the base substrate and an orthographic projection of the second power supply voltage signal lines on the base substrate.

In some embodiments, the first electrode block includes a first opening region, and an orthographic projection of the first opening region on the base substrate overlaps with an orthographic projection of the first gate line on the base substrate.

In some embodiments, the array substrate further includes a plurality of first connection portions arranged on the base substrate, the first connection portions are arranged at intervals along the first direction; the first connection portion is connected to the initialization voltage signal line through a third through hole, and the first connection portion is connected to an active region of the thin film transistor through a fourth through hole;
an orthographic projection of the third through hole on the base substrate is located at an intersection of an orthographic projection of the first connection portion on the base substrate and an orthographic projection of the initialization voltage signal line on the base substrate;
an orthographic projection of the fourth through hole on the base substrate is located at an overlapped position of the orthographic projection of the first connection portion on the base substrate and an orthographic projection of the active region of the thin film transistor on the base substrate.

In some embodiments, the metal blocks further includes: a plurality of second electrode blocks,
an orthographic projection of the second electrode blocks on the base substrate overlaps with an orthographic projection of the second gate lines on the base substrate, an orthographic projection of the first reference voltage signal lines on the base substrate, and an orthographic projection of the initialization voltage signal lines on the base substrate; or, an orthographic projection of the second electrode blocks on the base substrate overlaps with an orthographic projection of the first reference voltage signal lines on the base substrate and an orthographic projection of the initialization voltage signal lines on the base substrate; the orthographic projection of the second electrode blocks on the base substrate and an orthographic projection of the second signal lines on the base substrate are spaced apart from each other.

In some embodiments, the orthographic projection of the second electrode blocks on the base substrate and an orthographic projection of the first connection portions on the base substrate are spaced apart from each other.

In some embodiments, the second electrode block is connected to the first connection portion to form a whole.

In some embodiments, the second electrode block includes a second opening region, wherein an orthographic projection of the second opening region on the base substrate overlaps with an orthographic projection of the second gate line on the base substrate.

In some embodiments, the metal blocks further include: a plurality of third electrode blocks, an orthographic projection of the third electrode blocks on the base substrate overlaps with the orthographic projection of the first gate lines on the base substrate;
the third electrode block is connected to the first gate line through a fifth through hole, and an orthographic projection of the fifth through hole on the base substrate overlaps with an orthographic projection of the third electrode block on the base substrate;
the orthographic projection of the third electrode blocks on the base substrate is spaced apart from an orthographic projection of the second signal lines, the orthographic projection of the first electrode blocks, and the orthographic projection of the second electrode blocks on the base substrate.

In some embodiments, the metal blocks further includes: a plurality of fourth electrode blocks, an orthographic projection of the fourth electrode blocks on the base substrate overlaps with an orthographic projection of the second gate lines on the base substrate;
the fourth electrode block is connected to the second gate line through a sixth through hole, and an orthographic projection of the sixth through hole on the base substrate overlaps with an orthographic projection of the fourth electrode block on the base substrate;
the orthographic projection of the fourth electrode blocks on the base substrate is spaced apart from an orthographic projection of the second signal lines on the base substrate, the orthographic projection of the first electrode blocks on the base substrate, and the orthographic projection of the second electrode blocks on the base substrate.

In some embodiments, the array substrate further includes: a plurality of first electrodes arranged on the base substrate, wherein an orthographic projection of the first electrode on the base substrate overlaps with an orthographic projection of a gate of the thin film transistor on the base substrate;
an orthographic projection of the first gate line on the base substrate and an orthographic projection of the second gate line on the base substrate are respectively located on different sides of the orthographic projection of the first electrode on the base substrate;
an orthographic projection of the light emitting control signal line on the base substrate is located between the orthographic projection of the first power supply voltage signal line on the base substrate and the orthographic projection of the first gate line on the base substrate;
the orthographic projection of the first reference voltage signal line on the base substrate is located between an orthographic projection of the initialization voltage signal line and the orthographic projection of the second gate line on the base substrate.

In some embodiments, the first electrodes, the first electrode blocks and the second electrode blocks are arranged to be spaced apart from each other.

In some embodiments, the first electrode extends along the second direction to a position of the first electrode block and is connected to the first electrode block to form a whole, and\or, the first electrode extends along the second direction to a position of the second electrode block and is connected to the second electrode block to form a whole.

In some embodiments, the array substrate further includes: a plurality of second connection portions arranged on the base substrate, wherein the second connection portions are arranged at intervals along the first direction; the second connection portion is connected to active regions of the thin film transistors through a seventh through hole and an eighth through hole; an orthographic projection of the seventh through hole on the base substrate and an orthographic projection of the eighth through hole on the base substrate are located on different sides of an orthographic projection of the first gate line on the base substrate.

In some embodiments, the display panel further including: a plurality of sub-pixels, wherein at least one of the plurality of sub-pixels includes a pixel circuit and a light-emitting device; the sub-pixel includes the plurality of thin film transistors and a storage capacitor; wherein the plurality of thin film transistors include: a first transistor, a second transistor, a third transistor, and a driving transistor;
a gate of the first transistor is coupled to the first gate line, a first electrode of the first transistor is coupled to the data line, and a second electrode of the first transistor is coupled to a gate of the driving transistor;
a gate of the second transistor is coupled to the second gate line, a first electrode of the second transistor is coupled to the first reference voltage signal line, and a second electrode of the second transistor is coupled to the gate of the driving transistor;
a gate of the third transistor is coupled to the light emitting control signal line, a first electrode of the third transistor is coupled to the first power supply voltage signal line, and a second electrode of the third transistor is coupled to a first electrode of the driving transistor;
the gate of the driving transistor is coupled to a first electrode of the storage capacitor, and a second electrode of the driving transistor is coupled to the light emitting device;
a second electrode of the storage capacitor is coupled to the initialization voltage signal line.

In some embodiments, the array substrate further includes:
a light shielding layer located on the base substrate;
a buffer layer located on a side of the light shielding layer facing away from the base substrate;
an active layer located on a side of the buffer layer facing away from the base substrate, wherein the active layer includes active regions of the thin film transistors;
a gate insulating layer located on a side of the active layer facing away from the base substrate;
a first conductive layer located on a side of the gate insulating layer facing away from the base substrate, wherein the first conductive layer includes the first signal lines and gates of the thin film transistors;
an interlayer insulating layer located on a side of the first conductive layer facing away from the base substrate;
a second conductive layer located on a side of the interlayer insulating layer facing away from the base substrate, wherein the second conductive layer includes the second signal lines, the first connection portions, the second connection portions, the metal blocks and the first electrodes;
a planarization layer located on a side of the second conductive layer facing away from the base substrate;
an anode layer located on a side of the planarization layer facing away from the base substrate; and
a pixel defining layer arranged in a layer where the anode layer is arranged, and an orthographic projection of the pixel defining layer on the base substrate does not overlap with an orthographic projection of the anode layer on the base substrate.

In some embodiments, the anode layer is connected to the first electrode through an anode through hole;
the anode through hole is close to the second gate line, and an orthographic projection of the anode through hole on the base substrate overlaps with the orthographic projection of the first electrode on the base substrate; or, the anode through hole is close to the light emitting control signal line, and an orthographic projection of the anode through hole on the base substrate overlaps with an orthographic projection of the first electrode block on the base substrate and the orthographic projection of the first power supply voltage signal line on the base substrate; or, the anode through hole is close to the first gate line, and an orthographic projection of the anode through hole on the base substrate overlaps with an orthographic projection of the first electrode block on the base substrate and an orthographic projection of the light emitting control signal line on the base substrate.

In some embodiments, the array substrate further includes: a pixel definition layer arranged in the layer where the anode layer is arranged;
an orthographic projection of the pixel definition layer on the base substrate does not overlap with the orthographic projection of the anode layer on the base substrate, the orthographic projection of the metal blocks, an orthographic projection of the first connection portions on the base substrate, an orthographic projection of the second connection portions on the base substrate and an orthographic projection of the first electrodes on the base substrate;
the orthographic projection of the pixel definition layer on the base substrate overlaps with the orthographic projection of the second signal lines on the base substrate and the orthographic projection of the first power supply voltage signal lines on the base substrate.

In some embodiments, the display panel further including: an opposite substrate, the opposite substrate includes a black matrix region;
an orthographic projection of the black matrix region on the base substrate overlaps with the orthographic projection of the pixel definition layer on the base substrate.

In some embodiments, the orthographic projection of the black matrix region on the base substrate overlaps with the orthographic projection of the light emitting control signal lines on the base substrate and the orthographic projection of the anode through hole on the base substrate.

Some embodiments of the present disclosure provide a display device, including the aforementioned display panel.

### BRIEF DESCRIPTION OF FIGURES

FIG. 1 is a schematic diagram of a structure of some display panels provided by an embodiment of the present disclosure;

FIG. 2 is a schematic diagram of a structure of other display panels provided by an embodiment of the present disclosure;

FIG. 3 is a schematic diagram of a structure of pixel circuits in some sub-pixels provided in an embodiment of the present disclosure;

FIG. 4 is a schematic diagram of some cross-sectional structures in the schematic diagram of a layout structure shown in FIG. 2;

FIG. 5 is a schematic diagram of other cross-sectional structures in the schematic diagram of the layout structure shown in FIG. 2;

FIG. 6 is a schematic diagram of a structure of other display panels provided by an embodiment of the present disclosure;

FIG. 7 is a schematic diagram of some cross-sectional structures in the schematic diagram of a layout structure shown in FIG. 6;

FIG. 8 is a schematic diagram of other cross-sectional structures in the schematic diagram of the layout structure shown in FIG. 6;

FIG. 9 is a schematic diagram of other cross-sectional structures in the schematic diagram of the layout structure shown in FIG. 6;

FIG. 10 is a schematic diagram of a structure of some further display panels provided by an embodiment of the present disclosure;

FIG. 11 is a schematic diagram of some cross-sectional structures in the schematic diagram of a layout structure shown in FIG. 10;

FIG. 12 is a schematic diagram of a structure of some further display panels provided by an embodiment of the present disclosure;

FIG. 13 is a schematic diagram of some cross-sectional structures in the schematic diagram of a layout structure shown in FIG. 12;

FIG. 14 is a schematic diagram of other cross-sectional structures in the schematic diagram of the layout structure shown in FIG. 12;

FIG. 15 is a schematic diagram of a structure of some further display panels provided by an embodiment of the present disclosure;

FIG. 16 is a schematic diagram of a structure of some further display panels provided by an embodiment of the present disclosure;

FIG. 17 is a schematic diagram of a structure of some further display panels provided by an embodiment of the present disclosure;

FIG. 18 is a schematic diagram of a structure of some further display panels provided by an embodiment of the present disclosure;

FIG. 19 is a schematic diagram of a structure of some further display panels provided by an embodiment of the present disclosure;

FIG. 20 is a schematic diagram of a structure of some further display panels provided by an embodiment of the present disclosure;

FIG. 21 is a schematic diagram of a structure of some further display panels provided by an embodiment of the present disclosure;

FIG. 22 is a schematic diagram of some cross-sectional structures in the schematic diagram of a layout structure shown in FIG. 21;

FIG. 23 is a schematic diagram of a structure of some further display panels provided by an embodiment of the present disclosure;

FIG. 24 is a schematic diagram of some cross-sectional structures in the schematic diagram of a layout structure shown in FIG. 23;

FIG. 25 is a schematic diagram of other cross-sectional structures in the schematic diagram of the layout structure shown in FIG. 23;

FIG. 26 is a schematic diagram of a structures of some further display panels provided in an embodiment of the present disclosure.

### DETAILED DESCRIPTION

In order to make the purpose, technical solution and advantages of the embodiments of the present disclosure clearer, the technical solution of the embodiments of the present disclosure will be clearly and completely described below in conjunction with the drawings of the embodiments of the present disclosure. Obviously, the described embodiments are part of the embodiments of the present disclosure, not all of the embodiments. Moreover, in the absence of conflict, the embodiments in the present disclosure and the features in the embodiments can be combined with each other. Based on the described embodiments of the present disclosure, all other embodiments obtained by ordinary technicians in the field without creative work are within the scope of protection of the present disclosure.

Unless otherwise defined, the technical terms or scientific terms used in the present disclosure should be understood by people with ordinary skills in the field to which the present disclosure belongs. “First”, “second” and similar words used in the present disclosure do not indicate any order, quantity or importance, but are only used to distinguish different components. “Include” or “comprise” and similar words mean that the elements or objects appearing before the word cover the elements or objects listed after the word and their equivalents, without excluding other elements or objects. “Connect” or “connected” and similar words are not limited to physical or mechanical connections, but may include electrical connections, whether direct or indirect.

It should be noted that the sizes and shapes of the figures in the accompanying drawings do not reflect the actual proportions, and are only intended to illustrate the present disclosure. The same or similar reference numerals throughout represent the same or similar elements or elements having the same or similar functions.

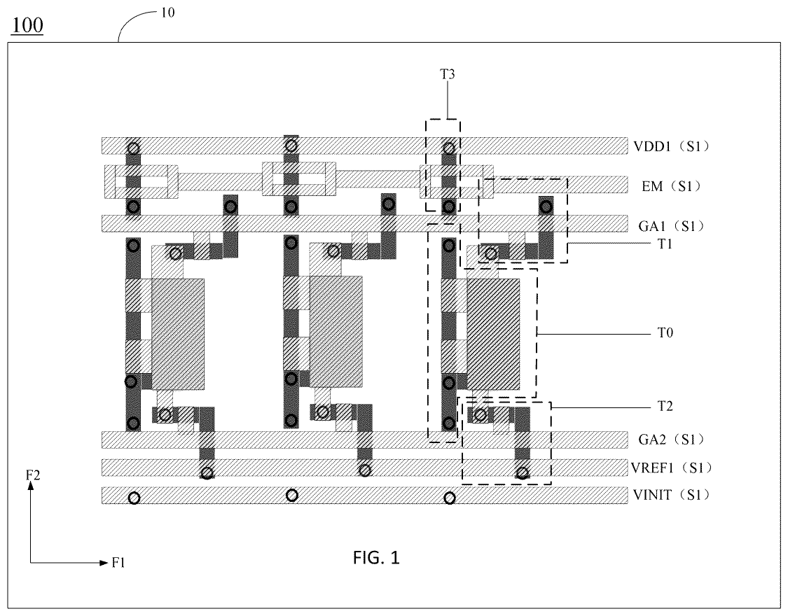

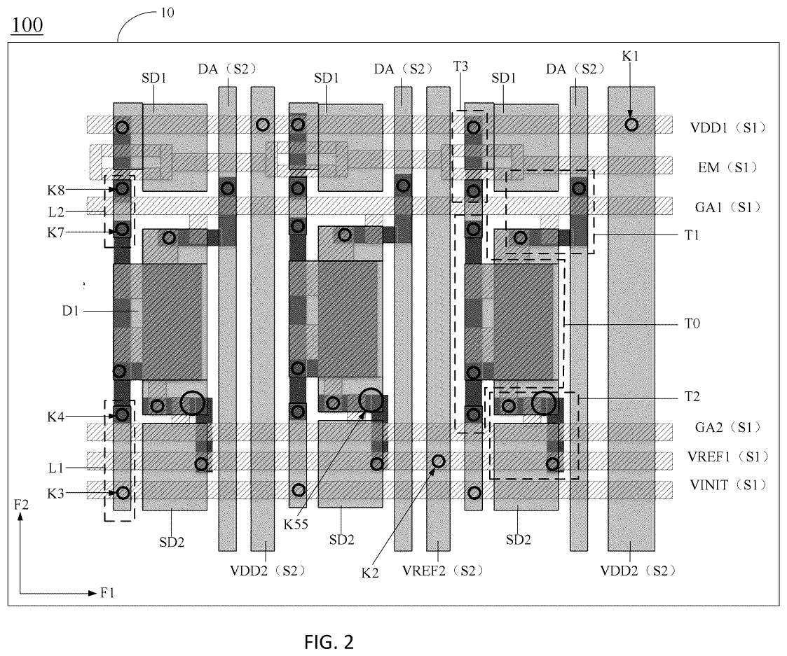

The present disclosure provides a display panel, as shown in FIG. 1 and FIG. 2, including: an array substrate 100 including: a base substrate 10 and a plurality of thin film transistors (such as T0, T1, T2, and T3 in FIG. 2) disposed on the base substrate 10, a plurality of first signal lines S1 extending along a first direction F1 and arranged at intervals along a second direction F2, a plurality of second signal lines S2 extending along a second direction F2 and arranged at intervals along the first direction F1, and a plurality of metal blocks (such as SD1 and SD2 in FIG. 2) arranged at intervals along the first direction F1.

The orthographic projection of the first signal line S1 on the base substrate 10 intersects with the orthographic projection of the second signal line S2 on the base substrate 10. The orthographic projection of the metal block (such as SD1 and SD2 in FIG. 2) on the base substrate 10 overlaps with the orthographic projection of the first signal line S1 on the base substrate 10, and the orthographic projection of the metal block (such as SD1 and SD2 in FIG. 2) on the base substrate 10 does not overlap with the orthographic projection of the second signal line S2 on the base substrate 10.

The embodiment of the present disclosure arranges a plurality of thin film transistors, a plurality of first signal lines extending in a first direction and spaced apart in a second direction, a plurality of second signal lines extending in a second direction and spaced apart in the first direction, and a plurality of metal blocks spaced apart in the first direction on a base substrate, and makes the orthographic projection of the metal block on the base substrate overlap with the orthographic projection of the first signal line on the base substrate, so that the orthographic projection of the metal block on the base substrate does not overlap with the orthographic projection of the second signal line on the base substrate, thereby improving the flatness of the flat layer of the pixel, avoiding the phenomenon of unevenness in the pixel, thereby improving the performance of the display device and the display effect of the display device.

Moreover, in addition to improving flatness, the metal block of the embodiment of the present disclosure can also serve as a shielding electrode, shielding crosstalk between multiple signal lines, and shielding crosstalk between multiple signal lines and other conductive layers (such as the anode of the light-emitting device), thereby improving display quality.

In some embodiments of the present disclosure, as shown in FIG. 1 and FIG. 2, the first signal lines S1 and the second signal lines S2 are arranged in different layers. The metal blocks (such as SD1 and SD2 in FIG. 2) and the second signal lines S2 are arranged on the same layer. The first signal lines S1 include: a plurality of first gate lines GA1, a plurality of second gate lines GA2, a plurality of first power supply voltage signal lines VDD1, a plurality of first reference voltage signal lines VREF1, a plurality of initialization voltage signal lines VINIT and a plurality of light emitting control signal lines EM. The second signal lines S2 include: a plurality of data lines DA, a plurality of second power supply voltage signal lines VDD2 and a plurality of second reference voltage signal lines VREF2. The first power supply voltage signal line VDD1 is connected to the second power supply voltage signal line VDD2 through the first through hole K1. The orthographic projection of the first through hole K1 on the base substrate 10 is located at the intersection of the orthographic projection of the first power supply voltage signal line VDD1 and the orthographic projection of the second power supply voltage signal line VDD2 on the base substrate 10. The first reference voltage signal line VREF1 is connected to the second reference voltage signal line VREF2 through the second through hole K2. The orthographic projection of the second through hole K2 on the base substrate 10 is located at the intersection of the orthographic projection of the first reference voltage signal line VREF1 and the orthographic projection of the second reference voltage signal line VREF2 on the base substrate 10.

In some embodiments of the present disclosure, as shown in FIG. 2, the metal block includes: a plurality of first electrode blocks SD1. The orthographic projections of the first electrode blocks SD1 on the base substrate 10 overlap with the orthographic projection of the first power supply voltage signal line VDD1 and the orthographic projection of the light emitting control signal line EM on the base substrate 10.

In some embodiments of the present disclosure, as shown in FIG. 2, an orthographic projection of the first electrode block SD1 on the base substrate 10 and an orthographic projection of the second signal line S2 on the base substrate 10 are spaced apart from each other.

In some embodiments of the present disclosure, as shown in FIG. 2, the array substrate 100 also includes a plurality of first connection portions L1 arranged on the base substrate 10, and the first connection portions L1 are arranged at intervals along the first direction F1. The first connection portion L1 is connected to the initialization voltage signal line VINIT through the third through hole K3. The first connection portion L1 is connected to the active region of the thin film transistor (for example, T0 in FIG. 2) through the fourth through hole K4. The orthographic projection of the third through hole K3 on the base substrate 10 is located at the intersection of the first connection portion L1 and the orthographic projection of the initialization voltage signal line VINIT on the base substrate 10. The orthographic projection of the fourth through hole K4 on the base substrate 10 is located at the overlap of the orthographic projection of the first connection portion L1 and the orthographic projection of the active region of the thin film transistor (for example, T0 in FIG. 2) on the base substrate 10.

In some embodiments of the present disclosure, as shown in FIG. 2, the array substrate 100 also includes: a plurality of second connection portions L2 arranged on the base substrate 10, and the second connection portions L2 are arranged at intervals along the first direction F1. The second connection portion L2 is connected to the active region of the thin film transistor (for example, T0 in FIG. 2) through the seventh through hole K7. The second connection portion L2 is connected to the active region of the thin film transistor (for example, T3 in FIG. 2) through the eighth through hole K8. The orthographic projection of the seventh through hole K7 and the orthographic projection of the eighth through hole K8 on the base substrate 10 are located on different sides of the orthographic projection of the first gate line GA1 on the base substrate 10.

In some embodiments of the present disclosure, as shown in FIG. 2, the metal block also includes: a plurality of second electrode blocks SD2. The orthographic projection of the second electrode block SD2 on the base substrate 10 overlaps with the orthographic projection of the second gate line GA2, the first reference voltage signal line VREF1 and the initialization voltage signal line VINIT on the base substrate 10. The orthographic projection of the second electrode block SD2 on the base substrate 10 is spaced from the orthographic projection of the second signal line S2 on the base substrate 10.

In some embodiments of the present disclosure, as shown in FIG. 2, the array substrate 100 further includes: a plurality of first electrodes D1 arranged on the base substrate 10. The orthographic projection of the first electrode D1 on the base substrate 10 overlaps with the orthographic projection of the gate electrode of the thin film transistor (e.g., T0, T1, T2 in FIG. 2) on the base substrate 10. The orthographic projection of the first gate line GA1 and the orthographic projection of the second gate line GA2 on the base substrate 10 are respectively located on different sides of the orthographic projection of the first electrode D1 on the base substrate 10. The orthographic projection of the light emitting control signal line EM on the base substrate 10 is located between the first power supply voltage signal line VDD1 and the orthographic projection of the first gate line GA1 on the base substrate 10. The orthographic projection of the first reference voltage signal line VREF1 on the base substrate 10 is located between the orthographic projection of the initialization voltage signal line VINIT and the orthographic projection of the second gate line GA2 on the base substrate 10.

In some embodiments of the present disclosure, as shown in FIG. 2, the first electrode D1 is spaced apart from the first electrode block SD1 and the second electrode block SD2.

In the display panel provided by the embodiment of the present disclosure, the base substrate 10 may include a display region and a non-display region. The non-display region may surround the display region. The display region may include a plurality of pixel units. The pixel unit may include a plurality of sub-pixels. Exemplarily, the pixel unit may include a red sub-pixel, a green sub-pixel, and a blue sub-pixel, so that a color display may be achieved by mixing red, green, and blue. Alternatively, the pixel unit may also include a red sub-pixel, a green sub-pixel, a blue sub-pixel, and a white sub-pixel, so that a color display may be achieved by mixing red, green, blue, and white. Of course, in actual applications, the luminous color of the sub-pixels in the pixel unit may be designed and determined according to the actual application environment, and is not limited here.

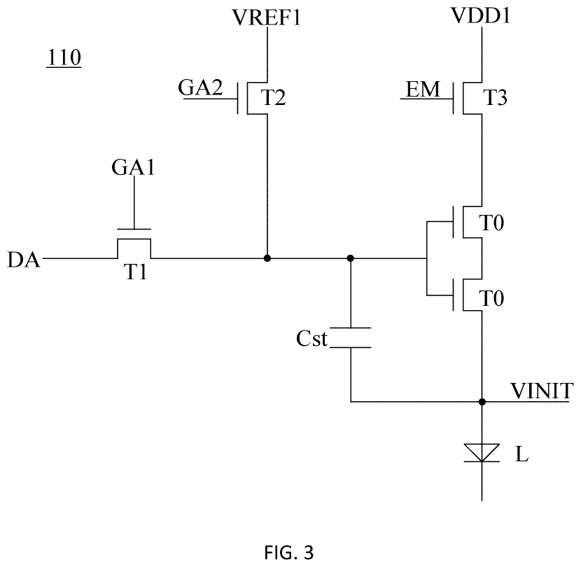

The display panel provided by the embodiment of the present disclosure, as shown in FIG. 3, at least one of the multiple sub-pixels may include: a pixel circuit 110 and a light-emitting device L. The pixel circuit 110 includes a thin film transistor (such as T0, T1, T2, T3 in FIG. 3) and a storage capacitor Cst, and generates an electrical signal through the interaction between the thin film transistor and the storage capacitor Cst. The generated electrical signal is input into the first electrode of the light-emitting device L, and a corresponding voltage is applied to the second electrode of the light-emitting device L, which can drive the light-emitting device L to emit light. The light-emitting device L may include at least one of an organic light emitting diode (OLED), a quantum dot light emitting diode (QLED), a micro light emitting diode (Micro LED), or a mini light emitting diode (Mini LED), etc. The light-emitting device L includes a first electrode, a light-emitting functional layer, and a second electrode arranged in a stacked manner. Exemplarily, the first electrode may be an anode, and the second electrode may be a cathode. The light-emitting functional layer may include a light-emitting layer. Furthermore, the light-emitting functional layer may also include film layers such as a hole injection layer, a hole transport layer, a light-emitting layer, an electron transport layer, and an electron injection layer. Of course, in practical applications, the light-emitting device L can be designed and determined according to the requirements of the actual application environment, and is not limited here.

In some embodiments of the present disclosure, as shown in FIG. 3, a plurality of thin film transistors include: a first transistor T1, a second transistor T2, a third transistor T3, and a driving transistor T0. A gate of the first transistor T1 is coupled to a first gate line GA1, a first electrode of the first transistor T1 is coupled to a data line DA, and a second electrode of the first transistor T1 is coupled to a gate of the driving transistor T0. A gate of the second transistor T2 is coupled to a second gate line GA2, a first electrode of the second transistor T2 is coupled to a first reference voltage signal line VREF1, and a second electrode of the second transistor T2 is coupled to a gate of the driving transistor T0. A gate of the third transistor T3 is coupled to a light emitting control signal line EM, a first electrode of the third transistor T3 is coupled to a first power supply voltage signal line VDD1, and a second electrode of the third transistor T3 is coupled to a first electrode of the driving transistor T0. A gate of the driving transistor T0 is coupled to a first electrode of a storage capacitor Cst, and a second electrode of the driving transistor T0 is coupled to a light emitting device L. A second electrode of the storage capacitor Cst is coupled to an initialization voltage signal line VINIT.

Exemplarily, the first electrode and the second electrode of the transistor can be determined as a source or a drain according to actual applications, which is not limited here.

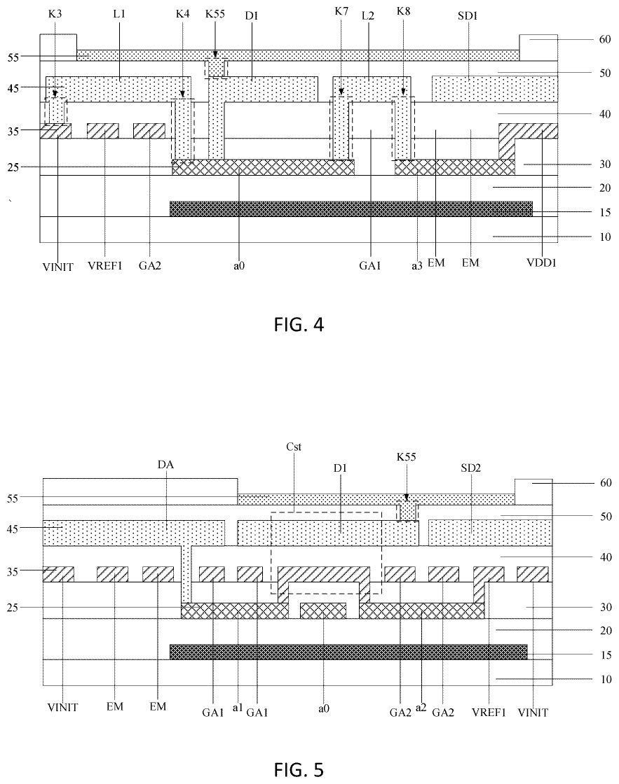

In some embodiments of the present disclosure, as shown in FIG. 4 and FIG. 5, the array substrate 100 further includes:
a light shielding layer 15 located on the base substrate 10;
a buffer layer 20 located on a side of the light shielding layer 15 facing away from the base substrate 10;
an active layer 25 located on a side of the buffer layer 20 facing away from the substrate 10, and the active layer 25 includes an active region of the thin film transistor (e.g., a0, a1, a2, a3 in the figure);
a gate insulating layer 30 located on a side of the active layer 25 facing away from the base substrate 10;
a first conductive layer 35 located on a side of the gate insulating layer 30 facing away from the base substrate 10, and the first conductive layer 35 includes the first signal lines S1 and a gate of a thin film transistor;
an interlayer insulating layer 40 located on a side of the first conductive layer 35 facing away from the base substrate 10;
a second conductive layer 45 located on a side of the interlayer insulating layer 40 facing away from the base substrate 10, and the second conductive layer 45 includes a second signal line S2, a first connection portion L1, a second connection portion L2, a metal block (such as SD1 and SD2 in the figure) and a first electrode D1;
a planarization layer 50 located on a side of the second conductive layer 45 facing away from the base substrate 10;
an anode layer 55 located on a side of the planarization layer 50 facing away from the base substrate 10;
a pixel defining layer 60 disposed on the same layer as the anode layer 55, and the orthographic projection of the pixel defining layer 60 on the base substrate 10 does not overlap with the orthographic projection of the anode layer 55 on the base substrate 10.

Exemplarily, in combination with FIGS. 3 to 5, the active layer 25 can be formed by patterning a semiconductor material. The active layer 25 can be used to make the active region a1 of the first transistor T1, the active region a2 of the second transistor T2, the active region a3 of the third transistor T3, and the active region a4 of the driving transistor T0, each of which can include a source region, a drain region, and a channel region between the source region and the drain region. For example, the active layers of some transistors can be integrally arranged. Exemplarily, the active layer can be made of amorphous silicon, polycrystalline silicon, oxide semiconductor materials, etc. It should be noted that the source region and the drain region can be regions doped with n-type impurities or p-type impurities.

For example, as shown in FIG. 4 and FIG. 5, the materials of the first conductive layer 35, the second conductive layer 45, and the anode layer 55 may be conductive materials. For example, the conductive material may include metal materials or alloy materials such as aluminum, molybdenum, and titanium, and may also include metal oxides such as indium tin oxide (ITO). The embodiments of the present disclosure do not limit the materials of each functional layer.

Exemplarily, as shown in FIG. 4 and FIG. 5, the light-shielding layer 15, the buffer layer 20, the gate insulating layer 30, the interlayer insulating layer 40, the planarization layer 50, the pixel defining layer 60, etc. are all formed of insulating materials. According to needs, organic insulating materials such as polyimide, resin materials, etc. can be selected, and inorganic insulating materials such as silicon oxide, silicon nitride, silicon oxynitride, etc. can also be selected. The embodiments of the present disclosure do not specifically limit the materials of each functional layer.

The various structures in the first conductive layer 35 and the second conductive layer 45 can be formed by a patterning process, and the through holes can be formed by an etching process. It should be noted that the patterning process may include only a photolithography process, or may include a photolithography process and an etching step, and may also include other processes such as printing and ink jetting for forming a predetermined pattern. The photolithography process refers to a process for forming a pattern using a photoresist, a mask, an exposure machine, etc., including a process of film formation, exposure, and development. In specific implementation, the corresponding patterning process can be selected according to the structure formed in the present disclosure.

It should be noted that, as shown in FIG. 5, the orthographic projection of the first conductive layer 35 on the base substrate 10 and the orthographic projection of the first electrode D1 in the second conductive layer 45 on the base substrate 10 have an overlapping region. The first electrode D1 in the second conductive layer 45 and the second conductive layer 45 can constitute a storage capacitor Cst. The first conductive layer 35 can serve as the first electrode of the storage capacitor, and the first electrode D1 in the second conductive layer 45 can serve as the second electrode of the storage capacitor Cst.

In some embodiments of the present disclosure, as shown in FIG. 2, FIG. 4 and FIG. 5, the anode layer 55 is connected to the first electrode D1 through the anode through hole K55. The anode through hole K55 is close to the second gate line GA2, and the orthographic projection of the anode through hole K55 on the base substrate 10 overlaps with the orthographic projection of the first electrode D1 on the base substrate 10.

It should be noted that, as shown in FIG. 2, FIG. 4 and FIG. 5, the anode through hole K55 penetrates the planarization layer 50. The first through hole K1, the second through hole K2 and the third through hole K3 penetrate the interlayer insulating layer 40. The fourth through hole K4, the seventh through hole K7 and the eighth through hole K8 penetrate the interlayer insulating layer 40 and the gate insulating layer 30.

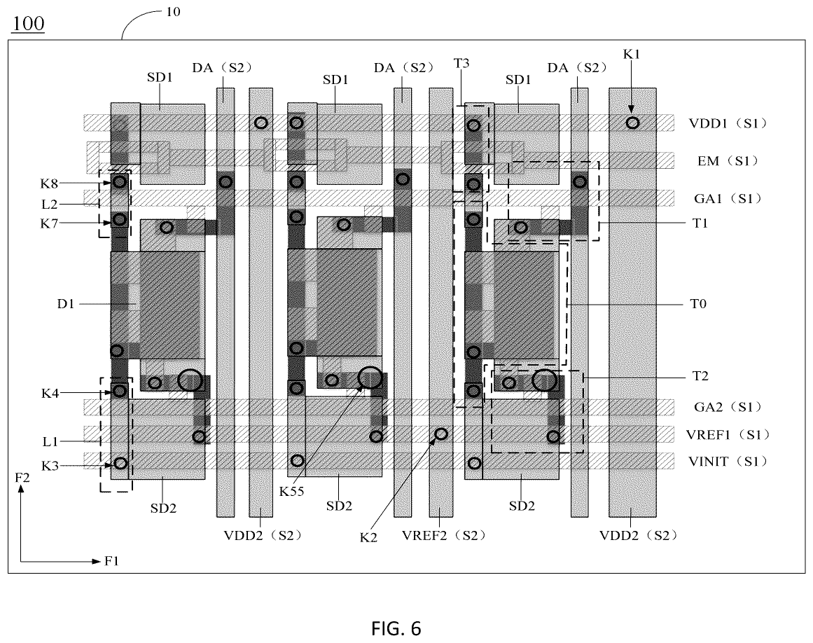

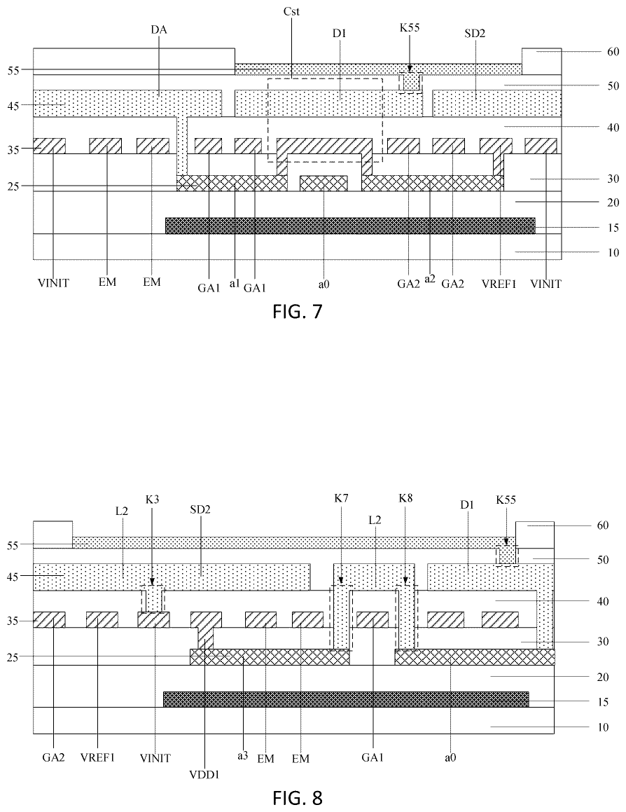

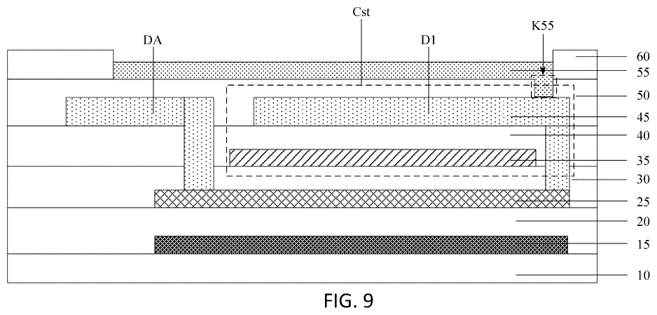

The structural schematic diagrams of other display panels provided by the embodiments of the present disclosure are shown in FIG. 6 to FIG. 9, which are modifications of the implementation of the above embodiments. The following only describes the differences between this embodiment and the above embodiments, and the similarities are not repeated here.

In other embodiments of the present disclosure, as shown in FIG. 6 to FIG. 9, the second electrode block SD2 is connected to the first connection portion L1 to form a whole. Exemplarily, since the second electrode block SD2 is integrally formed with the first connection portion L1, the second electrode block SD2 is electrically connected to the initialization voltage signal line VINIT through the third through hole K3.

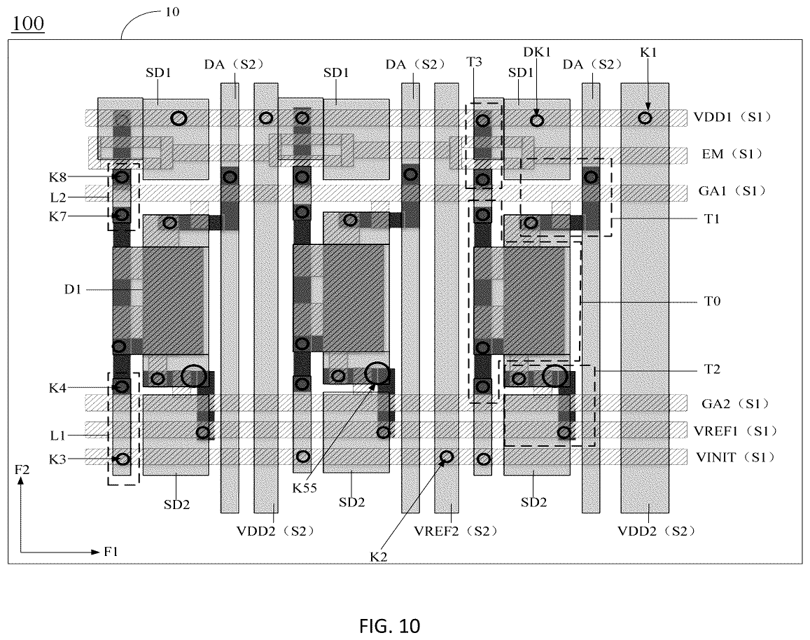

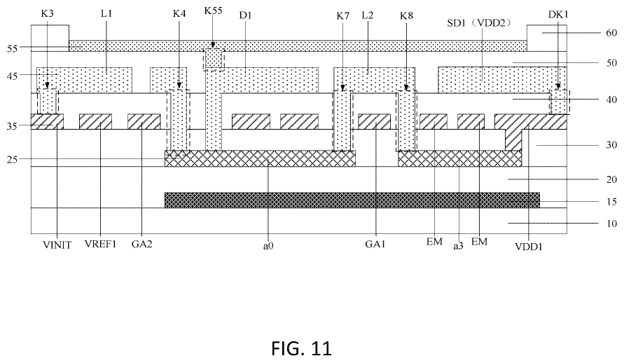

The structural schematic diagrams of some other display panels provided by the embodiments of the present disclosure are shown in FIG. 10 and FIG. 11, which are modifications of the implementation of the above embodiments. The following only describes the differences between this embodiment and the above embodiments, and the similarities are not repeated here.

In some other embodiments of the present disclosure, as shown in FIG. 10 and FIG. 11, the first electrode block SD1 is connected to the second power supply voltage signal line VDD2 to form a whole. The orthographic projection of the first electrode block SD1 on the base substrate 10 is spaced from the orthographic projection of the data line DA and the second reference voltage signal line VREF1 on the base substrate 10. Exemplarily, since the first electrode block SD1 is integrally formed with the second power supply voltage signal line VDD2, the first electrode block SD1 is connected to the first power supply voltage signal line VDD1 through the first through hole K1. In addition, the first electrode block SD1 is also connected to the first power supply voltage signal line VDD1 through the first conductive through hole DK1. The first conductive through hole DK1 penetrates the interlayer insulating layer 40.

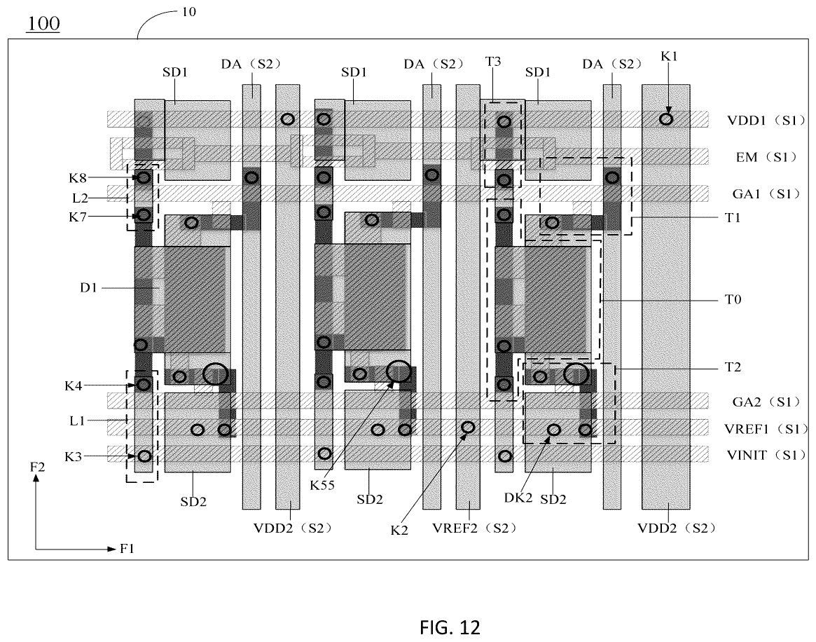

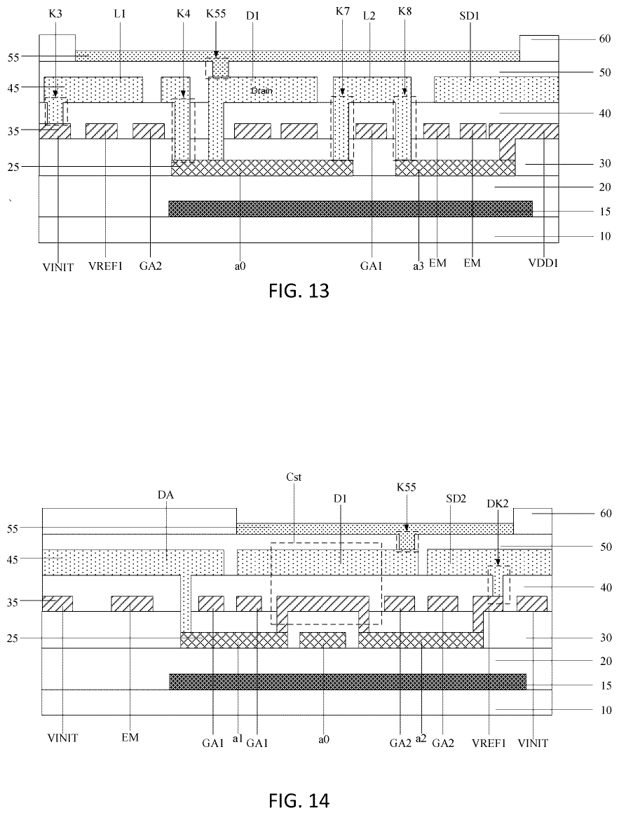

The structural schematic diagrams of some other display panels provided by the embodiments of the present disclosure are shown in FIG. 12 to FIG. 14, which are modifications of the implementation of the above embodiments. The following only describes the differences between this embodiment and the above embodiments, and the similarities are not repeated here.

In some other embodiments of the present disclosure, as shown in FIG. 12 to FIG. 14, the first electrode block SD1 is connected to the second reference voltage signal line VREF2 to form a whole. The orthographic projection of the first electrode block SD1 on the base substrate 10 is spaced from the orthographic projection of the data line DA and the second power supply voltage signal line VDD2 on the base substrate 10. Exemplarily, since the first electrode block SD1 is integrally formed with the second reference voltage signal line VREF2, the first electrode block SD1 is connected to the first reference voltage signal line VREF1 through the second through hole K2. The second electrode block SD2 is connected to the first reference voltage signal line VREF1 through the second conductive through hole DK2. The second conductive through hole DK2 penetrates the interlayer insulating layer 40.

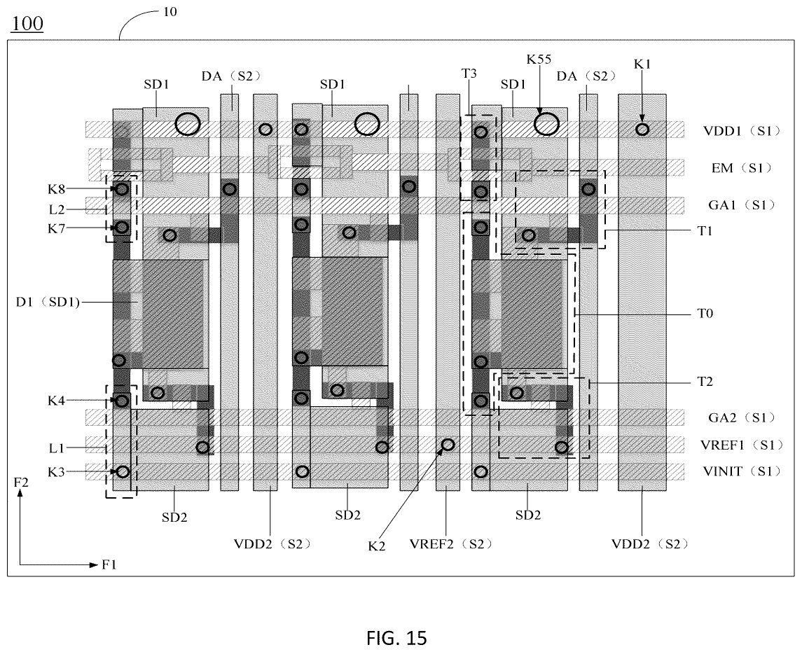

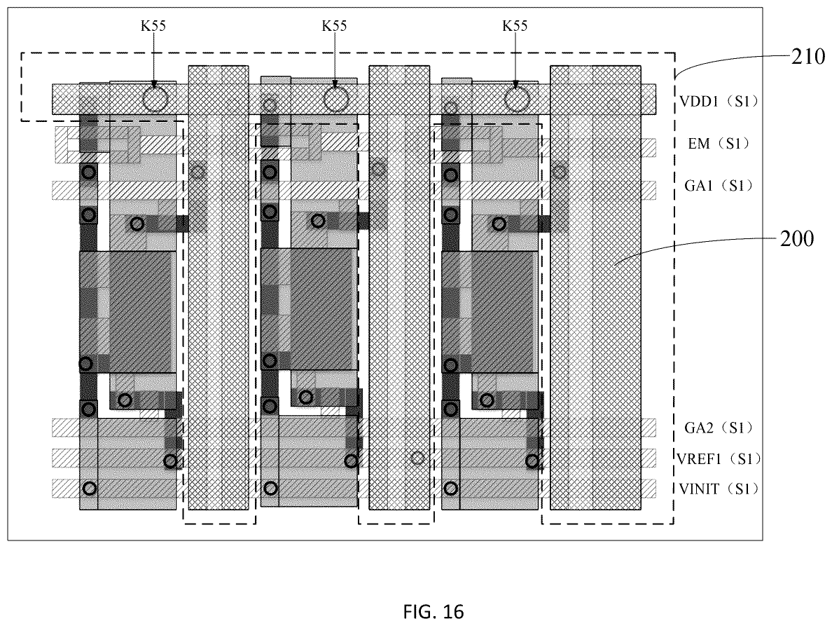

The structural schematic diagrams of some other display panels provided by the embodiments of the present disclosure are shown in FIG. 15 and FIG. 16, which are modified from the implementation of the above embodiments. The following only describes the differences between this embodiment and the above embodiments, and the similarities are not repeated here.

In some other embodiments of the present disclosure, as shown in FIG. 15, the orthographic projection of the first electrode block SD1 on the base substrate 10 overlaps with the orthographic projection of the first power supply voltage signal line VDD1, the orthographic projection of the light emitting control signal line EM and the orthographic projection of the first gate line G1 on the base substrate 10.

In some other embodiments of the present disclosure, as shown in FIG. 15, the first electrode D1 extends along the second direction F2 to the position of the first electrode block SD1, and is connected to the first electrode block SD1 to form a whole. Exemplarily, since the first electrode D1 is integrally formed with the first electrode block SD1, and the first electrode D1 is connected to the active layer of the thin film transistor, the first electrode block SD1 is connected to the active layer of the thin film transistor. In addition, the second electrode block SD2 is connected to the first connection portion L1 to form a whole. Exemplarily, since the second electrode block SD2 is integrally with the first connection portion L1, the second electrode block SD2 is electrically connected to the initialization voltage signal line VINIT through the third through hole K3.

In some other embodiments of the present disclosure, as shown in FIG. 15, the anode through hole K55 is close to the light emitting control signal line EM, and the orthographic projection of the anode through hole K55 on the base substrate 10 overlaps with the orthographic projections of the first electrode block SD1 and the first power supply voltage signal line VDD1 on the base substrate 10.

In some other embodiments of the present disclosure, as shown in FIG. 16, it further includes: an opposite substrate 200, the opposite substrate 200 includes a black matrix region 210. The orthographic projection of the black matrix area 210 on the base substrate overlaps with the orthographic projection of the first power supply voltage signal line VDD1 and the second signal line S2 on the base substrate 10. Then, the orthographic projection of the black matrix area 210 on the base substrate overlaps with the orthographic projection of the anode through hole K55 on the base substrate 10. Exemplarily, the opposite substrate is arranged opposite to the array substrate.

The disclosed embodiment improves the poor flatness characteristic caused by the large depth of the anode through hole by making the orthographic projection of the black matrix region on the base substrate overlap with the orthographic projection of the anode through hole on the base substrate, reduces the influence of flatness on the light output efficiency, and thus improves the display quality.

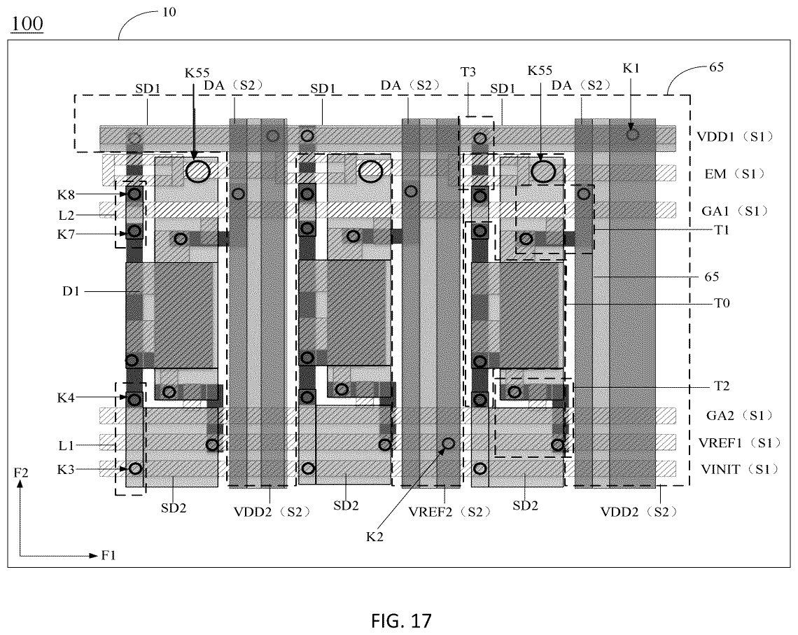

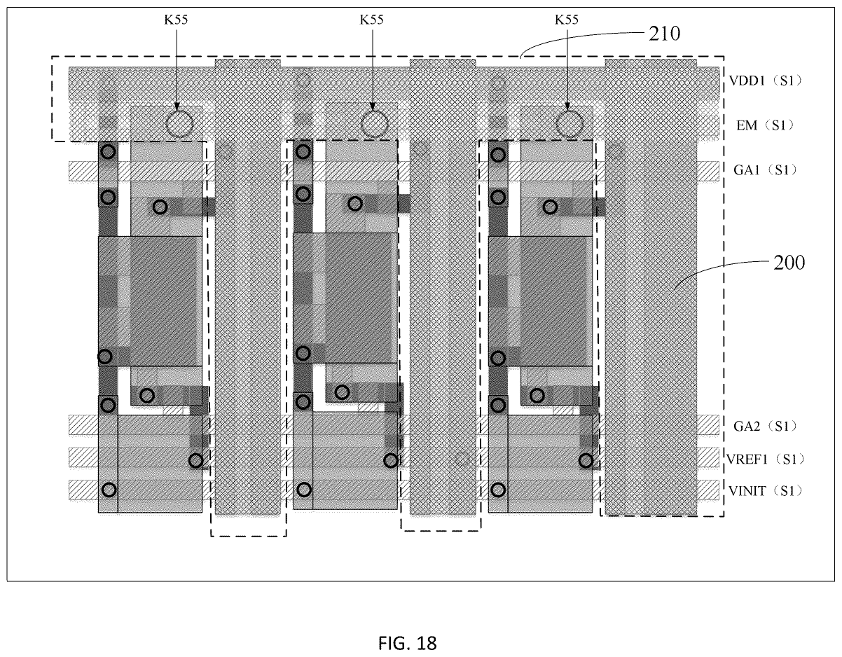

The structural schematic diagrams of some other display panels provided by the embodiments of the present disclosure are shown in FIG. 17 and FIG. 18, which are modified from the implementation of the above embodiments. The following only describes the differences between this embodiment and the above embodiments, and the similarities are not repeated here.

In some other embodiments of the present disclosure, as shown in FIG. 17, the orthographic projection of the first electrode block SD1 on the base substrate 10 overlaps with the orthographic projection of the light emitting control signal line EM and the orthographic projection of the first gate line GA1 on the base substrate 10.

In some other embodiments of the present disclosure, as shown in FIG. 17, the first electrode D1 extends along the second direction F2 to the position of the first electrode block SD1, and is connected to the first electrode block SD1 to form a whole. Exemplarily, since the first electrode D1 is integrally connected with the first electrode block SD1 are the same whole, and the first electrode D1 is connected to the active layer of the thin film transistor, the first electrode block SD1 is connected to the active layer of the thin film transistor. In addition, the second electrode block SD2 is connected to the first connection portion L1 to form a whole. Exemplarily, since the second electrode block SD2 is integrally connected with the first connection portion L1, the second electrode block SD2 is electrically connected to the initialization voltage signal line VINIT through the third through hole K3.

In some other embodiments of the present disclosure, as shown in FIG. 17, the anode through hole K55 is close to the first gate line GA1, and the orthographic projection of the anode through hole K55 on the base substrate 10 overlaps with the orthographic projection of the first electrode block SD1 and the orthographic projection of the light emitting control signal line EM on the base substrate 10.

In some other embodiments of the present disclosure, as shown in FIG. 17, the array substrate 100 also includes: a pixel definition layer 65, which is arranged on the same layer as the anode layer 55. The orthographic projection of the pixel definition layer 65 on the base substrate 10 does not overlap with the orthographic projection of the anode layer 55, the orthographic projection of the metal block (such as SD1 and SD2 in the figure), the orthographic projection of the first connection portion L1, the orthographic projection of the second connection portion L2 and the first electrode D1 on the base substrate 10. The orthographic projection of the pixel definition layer 65 on the base substrate 10 overlaps with the orthographic projection of the second signal line S2 and the first power supply voltage signal line VDD1 on the base substrate 10.

In some other embodiments of the present disclosure, as shown in FIG. 18, the opposite substrate 200 includes a black matrix region 210. The orthographic projection of the black matrix region 210 on the base substrate 10 overlaps with the orthographic projection of the pixel definition layer 65 on the base substrate 10.

In some other embodiments of the present disclosure, as shown in FIG. 18, the orthographic projection of the black matrix region 210 on the base substrate 10 overlaps with the orthographic projection of the light emitting control signal line EM and the orthographic anode through hole K55 on the base substrate.

In the embodiment of the present disclosure, the orthographic projection of the pixel definition layer 65 on the base substrate 10 is made not to overlap with the orthographic projection of the anode layer 55, the orthographic projection of the metal block (such as SD1 and SD2 in the figure), the orthographic projection of the first connection portion L1, the orthographic projection of the second connection portion L2 and the orthographic projection of the first electrode D1 on the base substrate 10, and the orthographic projection of the black matrix region 210 on the base substrate 10 is made to overlap with the orthographic projection of the light emitting control signal line EM and the orthographic projection of the anode through hole K55 on the base substrate. Even if all the non-luminous regions are arranged in regions wired along the first direction, the influence of unevenness on the light extraction efficiency, luminous efficiency, uniformity and life of the light-emitting device is reduced, and at the same time the aperture ratio of the light extraction is kept unchanged.

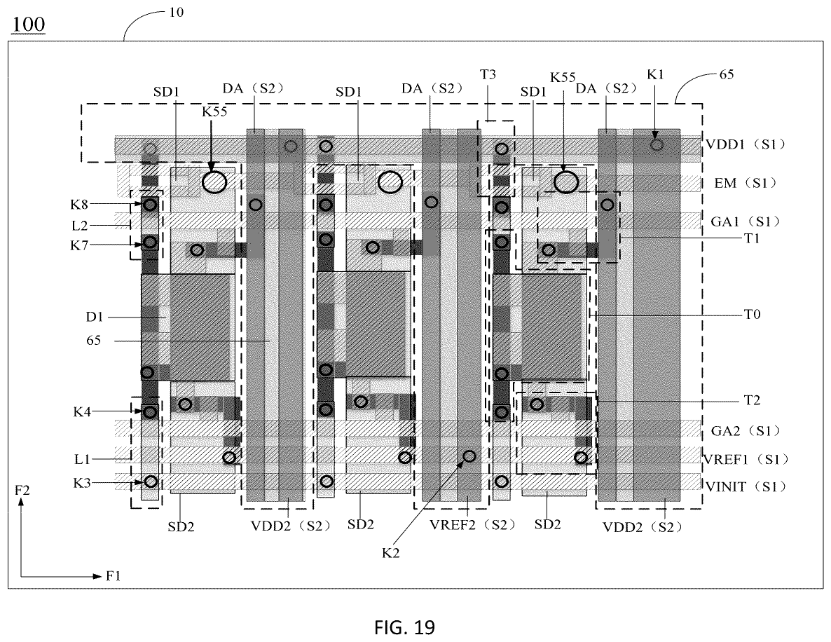

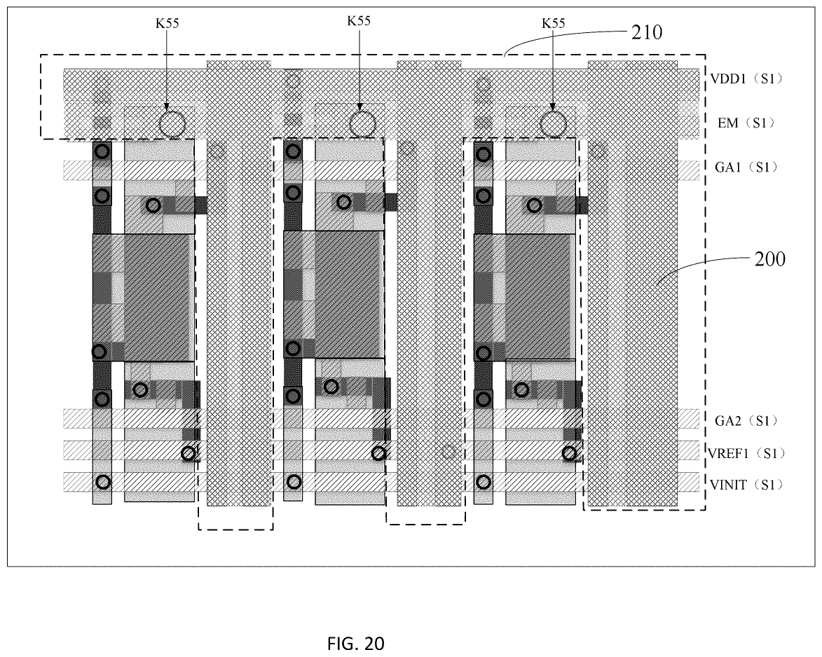

The structural schematic diagrams of some other display panels provided by the embodiments of the present disclosure are shown in FIG. 19 and FIG. 20, which are modified from the implementation of the above embodiments. The following only describes the differences between this embodiment and the above embodiments, and the similarities are not repeated here.

In some other embodiments of the present disclosure, as shown in FIG. 19, the first electrode D1 extends along the second direction F2 to the position of the first electrode block SD1, and is connected to the first electrode block SD1 to form a whole, and the first electrode D1 extends along the second direction F2 to the position of the second electrode block SD2, and is connected to the second electrode block SD2 to form a whole. Exemplarily, since the first electrode D1 is integrally formed with the first electrode block SD1 and the second electrode block SD2, and the first electrode D1 is connected to the active layer of the thin film transistor, the first electrode block SD1 and the second electrode block SD2 are connected to the active layer of the thin film transistor.

In some other embodiments of the present disclosure, as shown in FIG. 19, the orthographic projection of the first electrode block SD1 on the base substrate 10 overlaps with the orthographic projection of the light emitting control signal line EM and the orthographic projection of the first gate line GA1 on the base substrate 10.

In some other embodiments of the present disclosure, as shown in FIG. 19, the anode through hole K55 is close to the first gate line GA1, and the orthographic projection of the anode through hole K55 on the base substrate 10 overlaps with the orthographic projection of the first electrode block SD1 and the orthographic projection of the light emitting control signal line EM on the base substrate 10.

In some other embodiments of the present disclosure, as shown in FIG. 19, the array substrate 100 also includes: a pixel definition layer 65, which is arranged on the same layer as the anode layer 55. The orthographic projection of the pixel definition layer 65 on the base substrate 10 does not overlap with the orthographic projection of the anode layer 55, the orthographic projection of the metal block (for example, SD1 and SD2 in the figure), the orthographic projection of the first connection portion L1, the orthographic projection of the second connection portion L2 and the orthographic projection of the first electrode D1 on the base substrate 10. The orthographic projection of the pixel definition layer 65 on the base substrate 10 overlaps with the orthographic projection of the second signal line S2 and the orthographic projection of the first power supply voltage signal line VDD1 on the base substrate 10.

In some other embodiments of the present disclosure, as shown in FIG. 20, the opposite substrate 200 includes a black matrix region 210. The orthographic projection of the black matrix region 210 on the base substrate 10 overlaps with the orthographic projection of the pixel definition layer 65 on the base substrate 10.

In some other embodiments of the present disclosure, as shown in FIG. 20, the orthographic projection of the black matrix region 210 on the base substrate 10 overlaps with the orthographic projection of the light emitting control signal line EM and the orthographic projection of the anode through hole K55 on the base substrate.

In the embodiment of the present disclosure, the orthographic projection of the pixel definition layer 65 on the base substrate 10 is made not to overlap with the orthographic projection of the anode layer 55, the orthographic projection of the metal block (such as SD1 and SD2 in the figure), the orthographic projection of the first connection portion L1, the orthographic projection of the second connection portion L2 and the orthographic projection of the first electrode D1 on the base substrate 10; and the orthographic projection of the black matrix region 210 on the base substrate 10 is made to overlap with the orthographic projection of the light emitting control signal line EM and the orthographic projection of the anode through hole K55 on the base substrate, even if all the non-luminous regions are arranged in regions wired along the first direction, the influence of unevenness on the light extraction efficiency, luminous efficiency, uniformity and life of the light-emitting device is reduced, and at the same time the aperture ratio of the light extraction is kept unchanged.

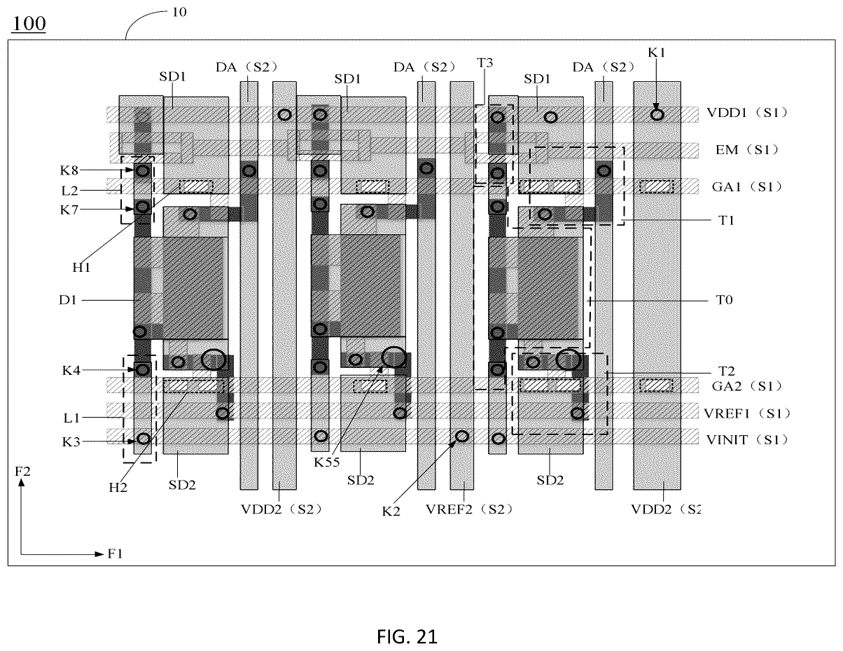

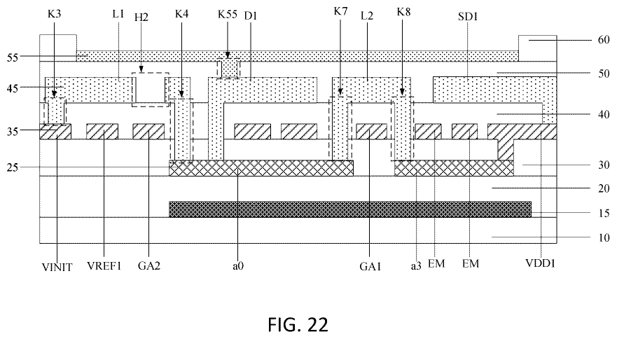

The structural schematic diagrams of some other display panels provided by the embodiments of the present disclosure are shown in FIG. 21 and FIG. 22, which are modified from the implementation of the above embodiments. The following only describes the differences between this embodiment and the above embodiments, and the similarities are not repeated here.

In some other embodiments of the present disclosure, as shown in FIG. 21 and FIG. 22, the first electrode block SD1 includes a first opening region H1, and an orthographic projection of the first opening region H1 on the base substrate 10 overlaps with an orthographic projection of the first gate line GA1 on the base substrate 10.

In some other embodiments of the present disclosure, as shown in FIG. 21 and FIG. 22, the second electrode block SD2 includes a second opening region H2, and an orthographic projection of the second opening region H2 on the base substrate 10 overlaps with the orthographic projection of the second gate line GA2 on the base substrate 10.

Exemplarily, as shown in FIG. 21, the second power supply voltage signal line VDD2 may also include an opening region. An orthographic projection of the opening region on the base substrate 10 overlaps with the orthographic projection of the first gate line GA1 and the orthographic projection of the second gate line GA2 on the base substrate 10.

Illustratively, the embodiment of the present disclosure makes the orthographic projection of the first opening region H1 on the base substrate 10 overlap with the orthographic projection of the first gate line GA1 on the base substrate 10, and makes the orthographic projection of the second opening area H2 on the base substrate 10 overlap with the orthographic projection of the second gate line GA2 on the base substrate 10, the load of the first gate line GA1 and the second gate line GA2 can be further reduced, thereby improving the display quality.

Exemplarily, the shapes of the above-mentioned opening regions include: rectangle, diamond, square, circle, grid, etc. The specific shape of the opening area can be set according to needs and is not limited here.

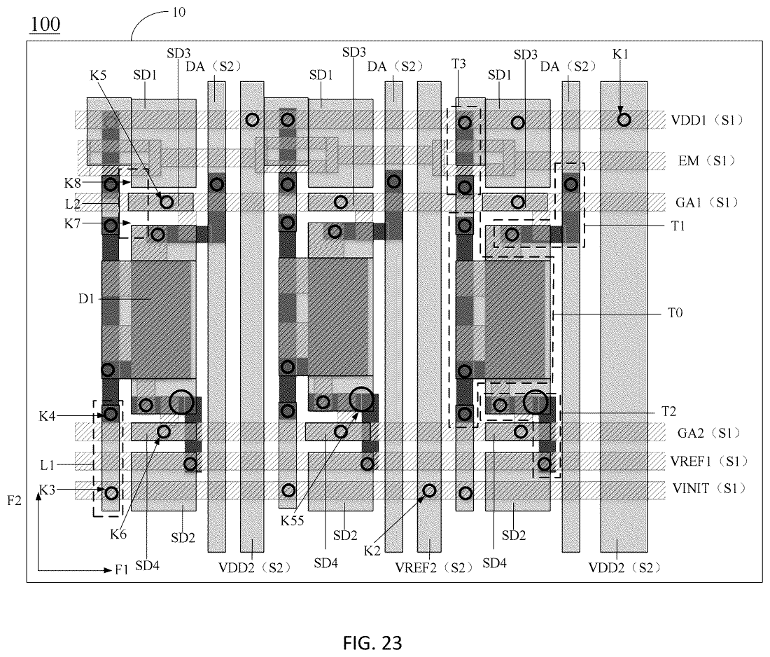

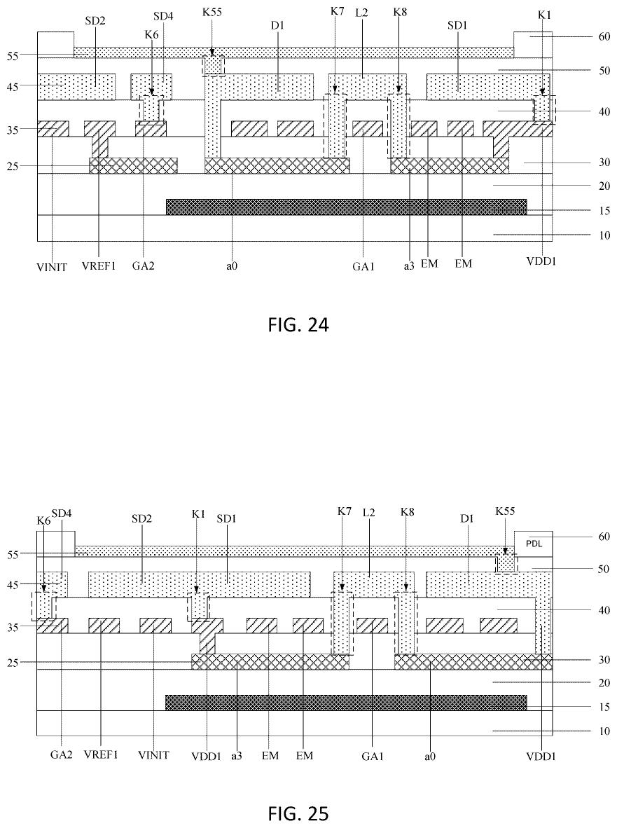

The structural schematic diagrams of some other display panels provided by the embodiments of the present disclosure are shown in FIG. 23 to FIG. 25, which are modifications of the implementation of the above embodiments. The following only describes the differences between this embodiment and the above embodiments, and the similarities are not repeated here.

In some other embodiments of the present disclosure, as shown in FIG. 23 to FIG. 25, the orthographic projection of the second electrode block SD2 on the base substrate 10 overlaps with the orthographic projection of the first reference voltage signal line VREF1 and the orthographic projection of the initialization voltage signal line VINIT on the base substrate 10.

In some other embodiments of the present disclosure, as shown in FIG. 23 to FIG. 25, the first electrode block SD1 is connected to the second power supply voltage signal line VDD2 to form a whole. The orthographic projection of the first electrode block SD1 on the base substrate 10 is spaced from the orthographic projection of the data line DA and the orthographic projection of the second reference voltage signal line VREF1 on the base substrate 10. Exemplarily, since the first electrode block SD1 is integrally formed with the second power supply voltage signal line VDD2, the first electrode block SD1 is connected to the first power supply voltage signal line VDD1 through the first through hole K1.

In some other embodiments of the present disclosure, as shown in FIG. 23 to FIG. 25, the metal block further includes: a plurality of third electrode blocks SD3. The orthographic projection of the third electrode block SD3 on the base substrate 10 overlaps with the orthographic projection of the first gate line GA1 on the base substrate 10. The third electrode block SD3 is connected to the first gate line GA1 through the fifth through hole K5. The orthographic projection of the fifth through hole K5 on the base substrate 10 overlaps with the orthographic projection of the third electrode block SD3 on the base substrate 10. The orthographic projection of the third electrode block SD3 on the base substrate 10 is spaced from the orthographic projection of the second signal line S2, the orthographic projection of the first electrode block SD1, and the orthographic projection of the second electrode block SD2 on the base substrate 10. Exemplarily, the fifth through hole K5 penetrates the interlayer insulating layer 40.

In some other embodiments of the present disclosure, as shown in FIG. 23 to FIG. 25, the metal block further includes: a plurality of fourth electrode blocks SD4. The orthographic projection of the fourth electrode block SD4 on the base substrate 10 overlaps with the orthographic projection of the second gate line GA2 on the base substrate 10. The fourth electrode block SD4 is connected to the second gate line GA2 through the sixth through hole K6. The orthographic projection of the sixth through hole K6 on the base substrate 10 overlaps with the orthographic projection of the fourth electrode block SD4 on the base substrate 10. The orthographic projection of the fourth electrode block SD4 on the base substrate 10 is spaced from the orthographic projection of the second signal line S2, the orthographic projection of the first electrode block SD1, and the orthographic projection of the second electrode block SD2 on the base substrate 10. Exemplarily, the sixth through hole K6 penetrates the interlayer insulating layer 40.

Illustratively, the disclosed embodiment arranges a plurality of third electrode blocks SD3. The orthographic projection of the third electrode block SD3 on the base substrate 10 overlaps with the orthographic projection of the first gate line GA1 on the base substrate 10. A plurality of fourth electrode blocks SD4 are arranged. The orthographic projection of the fourth electrode block SD4 on the base substrate 10 overlaps with the orthographic projection of the second gate line GA2 on the base substrate 10, that is, separate metal blocks are arranged above the first gate line GA1 and the second gate line GA2, respectively, thereby reducing the load and influence of the pulse AC signal on the first gate line GA1 and the second gate line GA2 and improving the display quality.

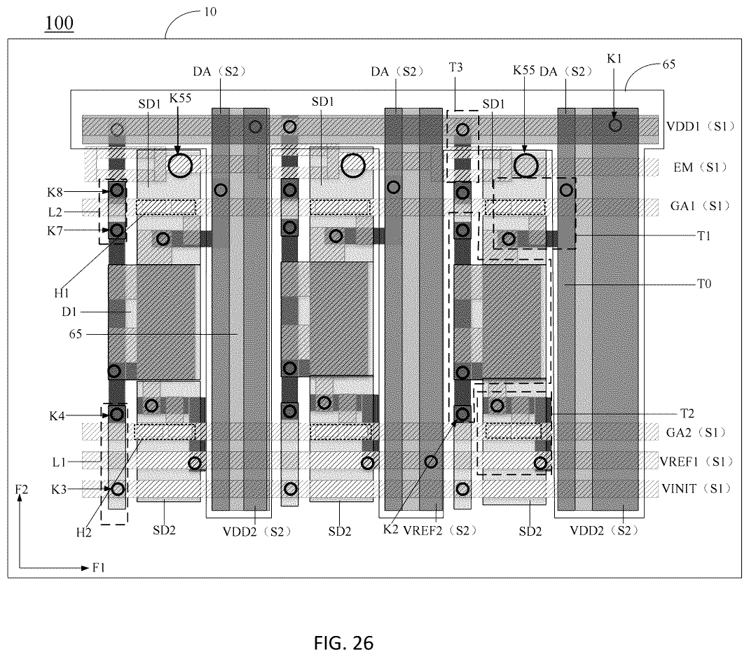

The structural schematic diagrams of some other display panels provided by the embodiments of the present disclosure are shown in FIG. 26, which are modified from the implementation of the above embodiment. The following only describes the differences between this embodiment and the above embodiment, and the similarities are not repeated here.

In some other embodiments of the present disclosure, as shown in FIG. 26, the orthographic projection of the first electrode block SD1 on the base substrate 10 overlaps with the orthographic projections of the light emitting control signal line EM and the orthographic projection of the first gate line GA1 on the base substrate 10.

In some other embodiments of the present disclosure, as shown in FIG. 26, the first electrode D1 extends along the second direction F2 to the position of the first electrode block SD1, and is connected to the first electrode block SD1 to form a whole, and the first electrode D1 extends along the second direction F2 to the position of the second electrode block SD2, and is connected to the second electrode block SD2 to form a whole. Exemplarily, since the first electrode D1 is integrally formed with the first electrode block SD1 and the second electrode block SD2, and the first electrode D1 is connected to the active layer of the thin film transistor, the first electrode block SD1 and the second electrode block SD2 are connected to the active layer of the thin film transistor.

In some other embodiments of the present disclosure, as shown in FIG. 26, the anode through hole K55 is close to the first gate line GA1, and the orthographic projection of the anode through hole K55 on the base substrate 10 overlaps with the orthographic projection of the first electrode block SD1 and the orthographic projection of the light emitting control signal line EM on the base substrate 10.

In some other embodiments of the present disclosure, as shown in FIG. 26, the first electrode block SD1 includes a first opening region H1. An orthographic projection of the first opening region H1 on the base substrate 10 overlaps with an orthographic projection of the first gate line GA1 on the base substrate 10.

In some other embodiments of the present disclosure, as shown in FIG. 26, the second electrode block SD2 includes a second opening region H2. An orthographic projection of the second opening region H2 on the base substrate 10 overlaps with the orthographic projection of the second gate line GA2 on the base substrate 10.

In some other embodiments of the present disclosure, as shown in FIG. 26, the array substrate 100 also includes: a pixel definition layer 65, which is arranged on the same layer as the anode layer 55. An orthographic projection of the pixel definition layer 65 on the base substrate 10 does not overlap with the orthographic projection of the anode layer 55, the orthographic projection of the metal block (for example, SD1 and SD2 in the figure), the orthographic projection of the first connection portion L1, the orthographic projection of the second connection portion L2 and the orthographic projection of the first electrode D1 on the base substrate 10. The orthographic projection of the pixel definition layer 65 on the base substrate 10 overlaps with the orthographic projection of the second signal line S2 and the orthographic projection of the first power supply voltage signal line VDD1 on the base substrate 10.

Illustratively, the embodiment of the present disclosure makes the orthographic projection of the first opening region H1 on the base substrate 10 overlap with the orthographic projection of the first gate line GA1 on the base substrate 10, and makes the orthographic projection of the second opening region H2 on the base substrate 10 overlap with the orthographic projection of the second gate line GA2 on the base substrate 10, the load of the first gate line GA1 and the second gate line GA2 can be further reduced, thereby improving the display quality.

Exemplarily, the shapes of the above-mentioned opening regions include: rectangle, diamond, square, circle, grid, etc. The specific shape of the opening regions can be set according to needs and is not limited here.

Based on the same inventive concept, the embodiment of the present disclosure further provides a display device, including the above display panel provided by the embodiment of the present disclosure. The implementation of the display device can refer to the embodiment of the above display panel, and the repeated parts will not be repeated.

In specific implementation, in the embodiments of the present disclosure, the display device may be any product or component with a display function, such as a mobile phone, an electronic watch, a tablet computer, a television, a monitor, a laptop computer, a digital photo frame, a navigator, etc. Other essential components of the display device are well understood by those skilled in the art, and are not described in detail here, nor should they be used as a limitation to the present disclosure.

Although the preferred embodiments of the present disclosure have been described, those skilled in the art may make additional changes and modifications to these embodiments once they have learned the basic creative concept. Therefore, the appended claims are intended to be interpreted as including the preferred embodiments and all changes and modifications falling within the scope of the present disclosure.

Obviously, those skilled in the art can make various changes and modifications to the embodiments of the present disclosure without departing from the spirit and scope of the embodiments of the present disclosure. Thus, if these modifications and variations of the embodiments of the present disclosure fall within the scope of the claims of the present disclosure and their equivalents, the present disclosure is also intended to include these modifications and variations.

1. A display panel, comprising:
an array substrate comprising: a base substrate, a plurality of thin film transistors arranged on the base substrate, a plurality of first signal lines extending along a first direction and arranged at intervals along a second direction, a plurality of second signal lines extending along the second direction and arranged at intervals along the first direction, and a plurality of metal blocks arranged at intervals along the first direction;
wherein an orthographic projection of the first signal lines on the base substrate intersects with an orthographic projection of the second signal lines on the substrate; an orthographic projection of the metal blocks on the base substrate overlaps with the orthographic projection of the first signal lines on the base substrate, and the orthographic projection of the metal blocks on the base substrate does not overlap with the orthographic projection of the second signal lines on the base substrate.

2. The display panel according to claim 1, wherein the first signal lines and the second signal lines are arranged on different layers; and the metal blocks and the second signal lines are arranged on the same layer;
wherein the first signal lines comprise: a plurality of first gate lines, a plurality of second gate lines, a plurality of first power supply voltage signal lines, a plurality of first reference voltage signal lines, a plurality of initialization voltage signal lines and a plurality of light emitting control signal lines;
wherein the second signal lines comprise: a plurality of data lines, a plurality of second power supply voltage signal lines and a plurality of second reference voltage signal lines;
wherein the first power supply voltage signal line is connected to the second power supply voltage signal line through a first through hole; an orthographic projection of the first through hole on the base substrate is located at an intersection of an orthographic projection of the first power supply voltage signal line on the base substrate and an orthographic projection of the second power supply voltage signal line on the base substrate;
wherein the first reference voltage signal line is connected to the second reference voltage signal line through a second through hole; an orthographic projection of the second through hole on the base substrate is located at an intersection of an orthographic projection of the first reference voltage signal line on the base substrate and an orthographic projection of the second reference voltage signal line on the base substrate.

3. The display panel according to claim 2, wherein the metal blocks comprise: a plurality of first electrode blocks,
an orthographic projection of the first electrode blocks on the base substrate overlaps with an orthographic projection of the first power supply voltage signal lines on the base substrate and an orthographic projection of the light emitting control signal lines on the base substrate;
or,
an orthographic projection of the first electrode blocks on the base substrate overlaps with an orthographic projection of the first power supply voltage signal lines on the base substrate, an orthographic projection of the light emitting control signal lines on the base substrate and an orthographic projection of the first gate lines on the base substrate;
or,
an orthographic projection of the first electrode blocks on the base substrate overlaps with an orthographic projection of the light emitting control signal lines on the base substrate and an orthographic projection of the first gate lines on the base substrate.

4. The display panel according to claim 3, wherein the orthographic projection of the first electrode blocks on the base substrate and an orthographic projection of the second signal lines on the base substrate are spaced apart from each other;
or
wherein the first electrode block is connected to the second power supply voltage signal line to form a whole;
wherein the orthographic projection of the first electrode blocks on the base substrate is spaced apart from an orthographic projection of the data lines on the base substrate and an orthographic projection of the second reference voltage signal lines on the base substrate;
or
wherein the first electrode block and the second reference voltage signal line are connected to form a whole;
wherein the orthographic projection of the first electrode blocks on the base substrate is spaced apart from an orthographic projection of the data lines on the base substrate and an orthographic projection of the second power supply voltage signal lines on the base substrate;
or
wherein the first electrode block comprises a first opening region, and an orthographic projection of the first opening region on the base substrate overlaps with an orthographic projection of the first gate line on the base substrate.

5-7. (canceled)

8. The display panel according to claim 3, wherein the array substrate further comprises a plurality of first connection portions arranged on the base substrate, the first connection portions are arranged at intervals along the first direction; the first connection portion is connected to the initialization voltage signal line through a third through hole, and the first connection portion is connected to an active region of the thin film transistor through a fourth through hole;
wherein an orthographic projection of the third through hole on the base substrate is located at an intersection of an orthographic projection of the first connection portion on the base substrate and an orthographic projection of the initialization voltage signal line on the base substrate;
wherein an orthographic projection of the fourth through hole on the base substrate is located at an overlapped position of the orthographic projection of the first connection portion on the base substrate and an orthographic projection of the active region of the thin film transistor on the base substrate.

9. The display panel according to claim 8, wherein the metal blocks further comprises:
a plurality of second electrode blocks,
an orthographic projection of the second electrode blocks on the base substrate overlaps with an orthographic projection of the second gate lines on the base substrate, an orthographic projection of the first reference voltage signal lines on the base substrate, and an orthographic projection of the initialization voltage signal lines on the base substrate;
or,
an orthographic projection of the second electrode blocks on the base substrate overlaps with an orthographic projection of the first reference voltage signal lines on the base substrate and an orthographic projection of the initialization voltage signal lines on the base substrate;
wherein the orthographic projection of the second electrode blocks on the base substrate and an orthographic projection of the second signal lines on the base substrate are spaced apart from each other.

10. The display panel according to claim 9, wherein the orthographic projection of the second electrode blocks on the base substrate and an orthographic projection of the first connection portions on the base substrate are spaced apart from each other;
or
wherein the second electrode block is connected to the first connection portion to form a whole;
or
wherein the second electrode block comprises a second opening region, wherein an orthographic projection of the second opening region on the base substrate overlaps with an orthographic projection of the second gate line on the base substrate.

11. (canceled)

12. (canceled)

13. The display panel according to claim 9, wherein the metal blocks further comprise: a plurality of third electrode blocks, an orthographic projection of the third electrode blocks on the base substrate overlaps with the orthographic projection of the first gate lines on the base substrate;
wherein the third electrode block is connected to the first gate line through a fifth through hole, and an orthographic projection of the fifth through hole on the base substrate overlaps with an orthographic projection of the third electrode block on the base substrate;
wherein the orthographic projection of the third electrode blocks on the base substrate is spaced apart from an orthographic projection of the second signal lines, the orthographic projection of the first electrode blocks, and the orthographic projection of the second electrode blocks on the base substrate.

14. The display panel according to claim 9, wherein the metal blocks further comprises: a plurality of fourth electrode blocks, an orthographic projection of the fourth electrode blocks on the base substrate overlaps with the orthographic projection of the second gate lines on the base substrate;
wherein the fourth electrode block is connected to the second gate line through a sixth through hole, and an orthographic projection of the sixth through hole on the base substrate overlaps with an orthographic projection of the fourth electrode block on the base substrate;
wherein the orthographic projection of the fourth electrode blocks on the base substrate is spaced apart from an orthographic projection of the second signal lines on the base substrate, the orthographic projection of the first electrode blocks on the base substrate, and the orthographic projection of the second electrode blocks on the base substrate.

15. The display panel according to claim 8, wherein the array substrate further comprises: a plurality of first electrodes arranged on the base substrate, wherein an orthographic projection of the first electrode on the base substrate overlaps with an orthographic projection of a gate of the thin film transistor on the base substrate;
wherein an orthographic projection of the first gate line on the base substrate and an orthographic projection of the second gate line on the base substrate are respectively located on different sides of the orthographic projection of the first electrode on the base substrate;
wherein an orthographic projection of the light emitting control signal line on the base substrate is located between the orthographic projection of the first power supply voltage signal line on the base substrate and the orthographic projection of the first gate line on the base substrate;
wherein the orthographic projection of the first reference voltage signal line on the base substrate is located between an orthographic projection of the initialization voltage signal line and the orthographic projection of the second gate line on the base substrate.

16. The display panel according to claim 15, wherein the first electrodes, the first electrode blocks and the second electrode blocks are arranged to be spaced apart from each other.

17. The display panel according to claim 15, wherein the first electrode extends along the second direction to a position of the first electrode block and is connected to the first electrode block to form a whole, and\or, the first electrode extends along the second direction to a position of the second electrode block and is connected to the second electrode block to form a whole.

18. The display panel according to claim 15, wherein the array substrate further comprises: a plurality of second connection portions arranged on the base substrate, wherein the second connection portions are arranged at intervals along the first direction;
the second connection portion is connected to active regions of the thin film transistors through a seventh through hole and an eighth through hole; an orthographic projection of the seventh through hole on the base substrate and an orthographic projection of the eighth through hole on the base substrate are located on different sides of an orthographic projection of the first gate line on the base substrate.

19. The display panel according to claim 2, further comprising: a plurality of sub-pixels, wherein at least one of the plurality of sub-pixels comprises a pixel circuit and a light-emitting device; the sub-pixel comprises the plurality of thin film transistors and a storage capacitor; wherein the plurality of thin film transistors comprise: a first transistor, a second transistor, a third transistor, and a driving transistor;
wherein a gate of the first transistor is coupled to the first gate line, a first electrode of the first transistor is coupled to the data line, and a second electrode of the first transistor is coupled to a gate of the driving transistor;
wherein a gate of the second transistor is coupled to the second gate line, a first electrode of the second transistor is coupled to the first reference voltage signal line, and a second electrode of the second transistor is coupled to the gate of the driving transistor;
wherein a gate of the third transistor is coupled to the light emitting control signal line, a first electrode of the third transistor is coupled to the first power supply voltage signal line, and a second electrode of the third transistor is coupled to a first electrode of the driving transistor;
wherein the gate of the driving transistor is coupled to a first electrode of the storage capacitor, and a second electrode of the driving transistor is coupled to the light emitting device;
wherein a second electrode of the storage capacitor is coupled to the initialization voltage signal line.

20. The display panel according to claim 18, wherein the array substrate further comprises:
a light shielding layer located on the base substrate;
a buffer layer located on a side of the light shielding layer facing away from the base substrate;
an active layer located on a side of the buffer layer facing away from the base substrate, wherein the active layer comprises active regions of the thin film transistors;
a gate insulating layer located on a side of the active layer facing away from the base substrate;
a first conductive layer located on a side of the gate insulating layer facing away from the base substrate, wherein the first conductive layer comprises the first signal lines and gates of the thin film transistors;
an interlayer insulating layer located on a side of the first conductive layer facing away from the base substrate;
a second conductive layer located on a side of the interlayer insulating layer facing away from the base substrate, wherein the second conductive layer comprises the second signal lines, the first connection portions, the second connection portions, the metal blocks and the first electrodes;
a planarization layer located on a side of the second conductive layer facing away from the base substrate;
an anode layer located on a side of the planarization layer facing away from the base substrate; and
a pixel defining layer arranged in a layer where the anode layer is arranged, and an orthographic projection of the pixel defining layer on the base substrate does not overlap with an orthographic projection of the anode layer on the base substrate.

21. The display panel according to claim 20, wherein the anode layer is connected to the first electrode through an anode through hole;
wherein the anode through hole is close to the second gate line, and an orthographic projection of the anode through hole on the base substrate overlaps with the orthographic projection of the first electrode on the base substrate;
or,
wherein the anode through hole is close to the light emitting control signal line, and an orthographic projection of the anode through hole on the base substrate overlaps with an orthographic projection of the first electrode block on the base substrate and the orthographic projection of the first power supply voltage signal line on the base substrate;
or
wherein the anode through hole is close to the first gate line, and an orthographic projection of the anode through hole on the base substrate overlaps with an orthographic projection of the first electrode block on the base substrate and an orthographic projection of the light emitting control signal line on the base substrate.

22. The display panel according to claim 21, wherein the array substrate further comprises: a pixel definition layer arranged in the layer where the anode layer is arranged;
wherein an orthographic projection of the pixel definition layer on the base substrate does not overlap with the orthographic projection of the anode layer on the base substrate, the orthographic projection of the metal blocks, an orthographic projection of the first connection portions on the base substrate, an orthographic projection of the second connection portions on the base substrate and an orthographic projection of the first electrodes on the base substrate;
wherein the orthographic projection of the pixel definition layer on the base substrate overlaps with the orthographic projection of the second signal lines on the base substrate and the orthographic projection of the first power supply voltage signal lines on the base substrate.

23. The display panel according to claim 22, further comprising: an opposite substrate, wherein the opposite substrate comprises a black matrix region;
wherein an orthographic projection of the black matrix region on the base substrate overlaps with the orthographic projection of the pixel definition layer on the base substrate.

24. The display panel according to claim 23, wherein the orthographic projection of the black matrix region on the base substrate overlaps with the orthographic projection of the light emitting control signal lines on the base substrate and the orthographic projection of the anode through hole on the base substrate.

25. A display device, comprising the display panel according to claim 1.
